(19) United States
(12) Patent Application Publication
(10) Pub. No.: US 2021/0378113 A1
(43) Pub. Date: Dec. 2, 2021

(54) DISPLAY DEVICE AND DISPLAY APPARATUS

(71) Applicant: BOE TECHNOLOGY GROUP CO., LTD., BEIJING (CN)

(72) Inventors: Zifeng WANG, BEIJING (CN); Xiaodong SHI, BEIJING (CN); Haiyan WAN, BEIJING (CN)

(73) Assignee: BOE TECHNOLOGY GROUP CO., LTD., BEIJING (CN)

(21) Appl. No.: 16/963,397

(22) PCT Filed: Jan. 15, 2020
(86) PCT No.: PCT/CN2020/072242

§ 371 Date: Jul. 20, 2020

(30) Foreign Application Priority Data
Feb. 15, 2019 (CN) 201920201731.0

(51) Int. Cl. H05K 5/02; H05K 5/00; H05K 7/20

(52) U.S. Cl. CPC H05K 5/0213; H05K 5/0017; F25D 29/005; H05K 5/0008; H05K 7/20963

(57) ABSTRACT

An embodiment of the present disclosure provides a display device and a display apparatus, the display device includes: a transparent structure and a display screen; the transparent structure including a first light transmission plate and a second light transmission plate which are oppositely set, edge regions of the first light transmission plate and the second light transmission plate being packaged by a seal assembly, to form a closed cavity; the display screen being set within the closed cavity, and an edge of the display screen being fixed to an inner wall of the closed cavity; the closed cavity being filled with inert gas.

### CROSS-REFERENCE TO RELATED APPLICATIONS

This application is a U.S. National Stage under 35 U.S.C. § 371 of International Application No. PCT/CN2020/072242, as filed on Jan. 15, 2020, which claims priority to the Chinese patent application No. 201920201731.0 filed on Feb. 15, 2019, and entitled “DISPLAY DEVICE AND DISPLAY APPARATUS”. The disclosure of each of these applications is incorporated by reference herein for all purposes.

### TECHNICAL FIELD

The present disclosure relates to a technical field of display, and specifically, to a display device and a display apparatus.

### BACKGROUND

With more and more applications of transparent display products such as a transparent show case, a transparent juicer, a transparent refrigerator, etc, currently these transparent display products mainly assemble and seal edges of display screens; however since these transparent display products are mainly applied indoors, a phenomenon of condensation often occurs in a freezer application in some cases where there are temperature differences, and furthermore, because of differences in southern and northern places, a problem of seal tightness occurs, and water vapor or dust, etc, enters.

### SUMMARY

According to a first aspect of the present disclosure, there is provided a display device comprising: a transparent structure and a display screen;

the transparent structure including a first light transmission plate and a second light transmission plate which are oppositely set, edge regions of the first light transmission plate and the second light transmission plate being packaged by a seal assembly, to form a closed cavity;

the display screen being set within the closed cavity, and an edge of the display screen being fixed to an inner wall of the closed cavity; the closed cavity being filled with inert gas.

Optionally, in a place which is within the closed cavity and is close to the seal assembly, there is also provided with a support which supports the first light transmission plate and the second light transmission plate, the support has water absorptivity.

Optionally, the support includes a casing and a water absorption material poured within the casing.

Optionally, the water absorption material is a molecular sieve or a drying adsorbent.

Optionally, the casing has at least one air hole.

Optionally, the seal assembly includes a first structure casing, a second structure casing, a seal glue, a first shock damping adhesive tape, a second shock damping adhesive tape and a position-limit structure;

wherein, the seal glue is packaged between opposite edge regions of the first light transmission plate and the second light transmission plate, the first structure casing is set outside the first light transmission plate and the seal glue, the second structure casing is set outside the second light transmission plate and the seal glue, the first structure casing and the second structure casing are fixed by a fastening structure on one side of the seal glue which is remote from a support;

the first shock damping adhesive tape is set between the first structure casing and the first light transmission plate, the second shock damping adhesive tape is set between the second structure casing and the second light transmission plate, the position-limit structure is set between the first structure casing and the joint of the first light transmission plate and the seal glue, the first shock damping adhesive tape is connected with the position-limit structure as one piece.

Optionally, the edge of the display screen and the first light transmission plate are fixed by an adhesive tape.

Optionally, ventilation openings are set in diagonal positions of the transparent structure; the ventilation openings communicate with the closed cavity; after the closed cavity is full of the inert gas, the ventilation openings are in a seal-up state.

Optionally, a touch screen is set on one side of the first light transmission plate which is remote from the display screen, the touch screen is connected with a touch sensor, the touch sensor is set between the first shock damping adhesive tape and the first structure casing, a third shock damping adhesive tape is further set between the touch sensor and the first structure casing.

Optionally, a light-emitting assembly is set outside the transparent structure, the light-emitting assembly is connected to the seal assembly.

Optionally, the light-emitting assembly includes a heat dissipation bracket and a light source, one end of the heat dissipation bracket is connected with the seal assembly, the other end is connected with the light source; a light out surface of the light source inclines and faces one side which is remote from the seal assembly.

Optionally, the heat dissipation bracket includes multiple heat dissipation columns; the heat dissipation columns are set on one side of the heat dissipation bracket which is remote from the light source.

Optionally, the outer surface of the heat dissipation column is a curved surface.

According to a second aspect of the present disclosure, there is provided a display apparatus, the display apparatus includes the display device according to any of the above mentioned embodiments and an apparatus body, the display device is set on at least one side of the apparatus body.

A display device provided by an embodiment of the present disclosure includes: a transparent structure and a display screen; the transparent structure including a first light transmission plate and a second light transmission plate which are oppositely set, edge regions of the first light transmission plate and the second light transmission plate being packaged by a seal assembly, to form a closed cavity; the display screen being set within the closed cavity, and an edge of the display screen being fixed to an inner wall of the closed cavity; the closed cavity being filled with inert gas.

### BRIEF DESCRIPTION OF THE DRAWINGS

In order to explain technical solutions in embodiments of the present disclosure more clearly, accompanying drawings used in the description of embodiments of the present disclosure will be briefly introduced in the following. Evidently, the accompanying drawings in the following description are only some embodiments of the present disclosure. Without creative labor, those skilled in the art may further obtain other accompanying drawings according to these accompanying drawings.

FIG. 1 is a structural diagram of a display device provided by an embodiment of the present disclosure.

FIG. 2 is a structural diagram of a supporting structure provided by an embodiment of the present disclosure.

FIG. 3 is a structural diagram of a front view of a display device provided by an embodiment of the present disclosure.

FIG. 4 is a structural diagram of another display device provided by an embodiment of the present disclosure.

### DETAILED DESCRIPTION

Hereinafter, a clear and complete description of technical solutions in embodiments of the present disclosure will be given in conjunction with drawings in embodiments of the present disclosure. Obviously, described embodiments are only a part of embodiments of the present disclosure, but not all of them. Based on embodiments in the present disclosure, all other embodiments obtained by those skilled in the art without creative labor fall within the protection scope of the present disclosure.

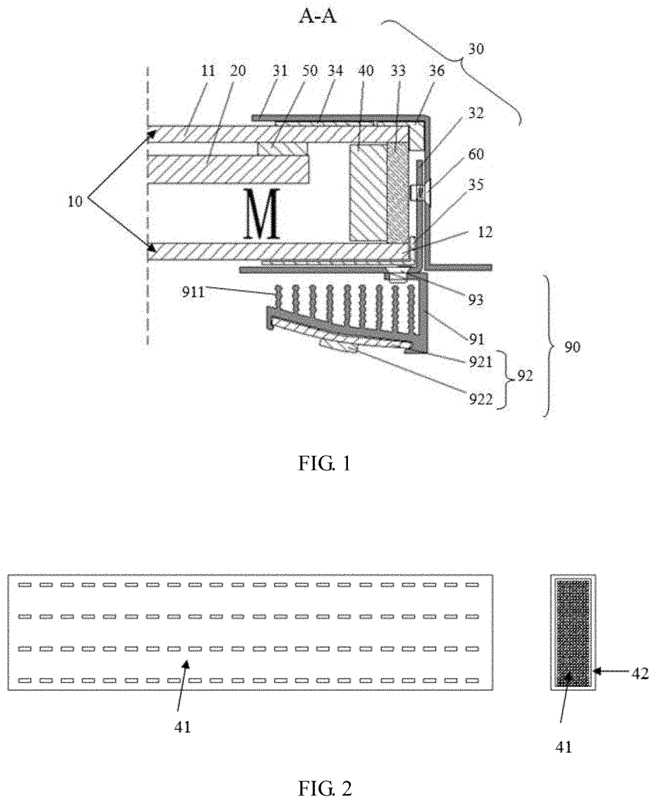

With reference to FIG. 1, a display device of an embodiment of the present disclosure is illustrated, comprising a transparent structure 10 and a display screen 20.

The transparent structure 10 includes a first light transmission plate 11 and a second light transmission plate 12 which are oppositely set, edge regions of the first light transmission plate 11 and the second light transmission plate 12 are packaged by a seal assembly 30, to form a closed cavity M.

The display screen 20 is set within the closed cavity M, and an edge of the display screen 20 is fixed to an inner wall of the closed cavity M; the closed cavity M is filled with inert gas.

In an embodiment of the present disclosure, the display screen 20 includes a transparent display screen, i.e., it may also be seen through when it displays.

In an embodiment of the present disclosure, the inert gas includes rare gas such as argon gas, helium gas, etc.

In an embodiment of the present disclosure, the first light transmission plate 11 and the second light transmission plate 12 may be transparent toughened glass, are used to protect the display screen 20, and transmit light emitted by the display screen 20.

In an embodiment of the present disclosure, in a place which is within the closed cavity M and is close to the seal assembly 30, there is also provided with a support 40 which supports the first light transmission plate 11 and the second light transmission plate 12, the support 40 has water absorptivity.

Occurrence of condensation on the display screen is mainly because, air saturation and humidity at different temperatures are different, air saturation humidity relates to air pressure, and after the temperature decreases, the corresponding air pressure also decreases, moisture of the air is also easily saturated and condensed. In an embodiment of the present disclosure, water content of the air in which the display screen 20 is located is decreased, so that, even when the display screen 20 is at a very low temperature, there is no saturation, and therefore, there is no condensation, in an embodiment of the present disclosure, the transparent structure 10 is manufactured as the closed structure, which is filled with the inert gas and is provided with the support 40 that has the water absorptivity. This can guarantee that the water content of the closed cavity M in which the display screen 20 is located is relatively low, prevent occurrence of condensation on the display screen 20.

In an embodiment of the present disclosure, the support 40 has both a function of supporting the first light transmission plate 11 and the second light transmission plate 12, and a function of water absorption.

In an embodiment of the present disclosure, with reference to FIG. 2, the support 40 includes a casing 41 and a water absorption material 42 poured within the casing.

In an embodiment of the present disclosure, the water absorption material is a molecular sieve or a drying adsorbent.

In an embodiment of the present disclosure, the casing 41 may be an aluminum material structure, may also be other stainless steel materials, and with reference to FIG. 2, the casing 41 is provided with air holes (as shown in FIG. 2), the moisture goes into the inner water absorption material 42 through the air holes. Wherein, the function of the casing includes supporting the first light transmission plate 11 and the second light transmission plate 12, and simultaneously protecting the display screen 20. When air passes nearby, the water absorption material may absorb the moisture in the air, decrease the water content in the air, decrease the possibility of condensation. The air holes may have any appropriate shapes or appropriate sizes.

In an embodiment of the present disclosure, the seal assembly 30 includes a first structure casing 31, a second structure casing 32, a seal glue 33, a first shock damping adhesive tape 34, a second shock damping adhesive tape 35 and a position-limit structure 36.

Wherein, the seal glue 33 is packaged between opposite edge regions of the first light transmission plate 11 and the second light transmission plate 12, the first structure casing 31 is set outside the first light transmission plate 11 and the seal glue 33, the second structure casing 32 is set outside the second light transmission plate 12 and the seal glue 33, the first structure casing 31 and the second structure casing 32 are fixed by a fastening structure 60 on one side of the seal glue which is remote from the support 40. The fastening structure 60 is for example a screw, may also be other fastening structures.

The first shock damping adhesive tape 34 is set between the first structure casing 31 and the first light transmission plate 11, the second shock damping adhesive tape 35 is set between the second structure casing 32 and the second light transmission plate 12, the position-limit structure 36 is set between the first structure casing 31 and the joint of the first light transmission plate 11 and the seal glue 33, the first shock damping adhesive tape 34 is connected with the position-limit structure 36 as one piece.

In an embodiment of the present disclosure, the position-limit structure 36 may cause a certain distance to be kept between the first structure casing 31 and the first light transmission plate 11, prevent damage to the first light transmission plate 11 due to squeeze of edges when the display device is installed on the display apparatus. Wherein, the material of the seal glue 33 and the position-limit structure 36 includes ultraviolet-cured glue or thermo-cured glue; the thickness of the position-limit structure 36 may be adjusted according to the length of the fastening structure (e.g., the screw), optionally 3 mm-8 mm.

In an embodiment of the present disclosure, the first shock damping adhesive tape 34 and the second shock damping adhesive tape 35 may avoid damage to the transparent structure 10 when the display device is subjected to impact. Wherein, the material of the first shock damping adhesive tape 34 and the second shock damping adhesive tape 35 includes foam rubber or silica gel.

In an embodiment of the present disclosure, the edge of the display screen 20 and the first light transmission plate 11 are fixed by an adhesive tape 50.

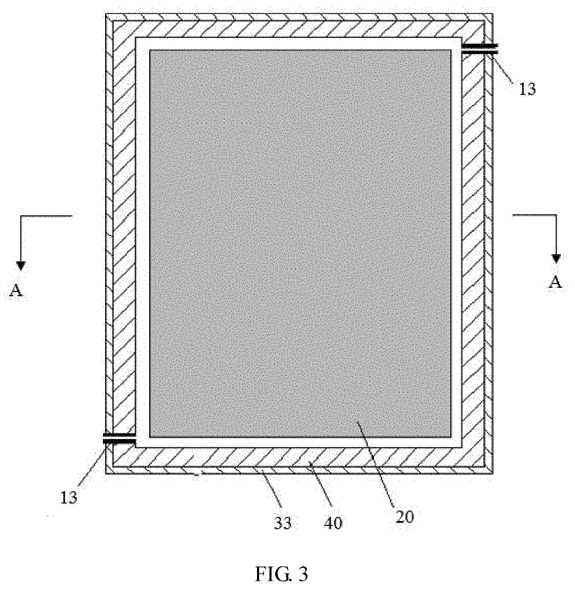

In an embodiment of the present disclosure, ventilation openings 13 are set in diagonal positions of the transparent structure 10 (as shown in FIG. 3); the ventilation openings 13 communicate with the closed cavity M; after the closed cavity M is full of the inert gas, the ventilation openings 13 are in a seal-up state.

In an embodiment of the present disclosure, with reference to FIG. 3, upon manufacturing the display device, the ventilation openings 13 are set in diagonal positions of the support 40 and the seal glue 33, wherein one of the ventilation openings 13 is used to charge the inert gas, the other is used to discharge the air. Wherein, the material of the ventilation openings 13 is a hot melt material such as ethylene-vinyl acetate copolymer, and when the ventilation of the inert gas is accomplished, the material is melted and deformed at a high temperature to seal up the ventilation openings 13.

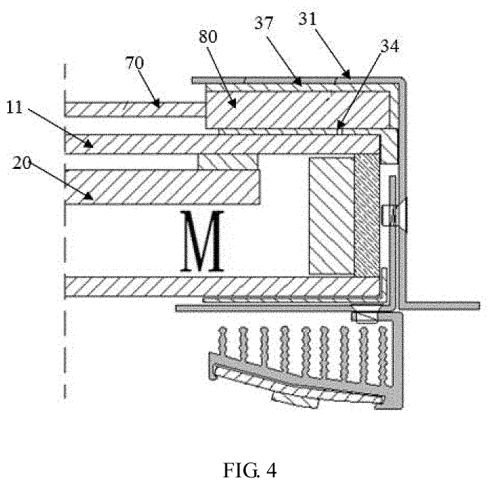

In an embodiment of the present disclosure, with reference to FIG. 4, a touch screen 70 is set on one side of the first light transmission plate 11 which is remote from the display screen 20, the touch screen 70 is connected with a touch sensor 80, the touch sensor 80 is set between the first shock damping adhesive tape 34 and the first structure casing 31, a third shock damping adhesive tape 37 is further set between the touch sensor 80 and the first structure casing 31.

In an embodiment of the present disclosure, adding the touch screen 70 on the one side of the first light transmission plate 11 may control the display of the display screen 20, facilitate user operations.

In an embodiment of the present disclosure, a light-emitting assembly 90 is set outside the transparent structure 10, the light-emitting assembly 90 is connected to the seal assembly 30.

In an embodiment of the present disclosure, the light-emitting assembly 90 illuminates in a direction opposite to the transparent structure 10, and when the display device is installed on a refrigerator or a freezer, the light-emitting assembly 90 may illuminate the interior of the refrigerator or the freezer.

In an embodiment of the present disclosure, the light-emitting assembly 90 includes a heat dissipation bracket 91 and a light source 92, one end of the heat dissipation bracket 91 is connected with the seal assembly 30, the other end is connected with the light source 92; a light out surface of the light source 92 inclines and faces one side which is remote from the seal assembly 30.

In an embodiment of the present disclosure, the light source 92 includes a circuit board 921 which powers the light source 92, and an LED lamp 922 which is set on the circuit board to emit light.

In an embodiment of the present disclosure, the inclination of the light out surface of the light source 92 may improve the luminescent efficiency of the light source 92.

In an embodiment of the present disclosure, the heat dissipation bracket 91 includes multiple heat dissipation columns 911; the heat dissipation columns 911 are set on one side of the heat dissipation bracket 91 which is remote from the light source.

In an embodiment of the present disclosure, the outer surface of the heat dissipation column 911 is a curved surface.

In an embodiment of the present disclosure, the heat dissipation bracket 91 may have an aluminum material, wherein, the heat dissipation bracket 91 may be fixed to the second structure casing 32 by a fastening structure 93.

In an embodiment of the present disclosure, the heat dissipation columns 911 may increase the heat dissipation area. They effectively reduce the heat on the light source side.

Another aspect of an embodiment of the present disclosure provides a display apparatus, the display apparatus includes the display device according to any of the above mentioned embodiments and an apparatus body, the display device is set on at least one side of the apparatus body, wherein, the display screen 20 is set to be remote from the apparatus body.

In an embodiment of the present disclosure, the display apparatus includes a refrigerator, a freezer, etc; wherein, the display device may function as one surface of the display apparatus.

To sum up, an embodiment of the present disclosure provides a display device, which includes: a transparent structure and a display screen; the transparent structure includes a first light transmission plate and a second light transmission plate which are oppositely set, edge regions of the first light transmission plate and the second light transmission plate are packaged by a seal assembly, to form a closed cavity; the display screen is set within the closed cavity, and an edge of the display screen is fixed to an inner wall of the closed cavity; the closed cavity is filled with inert gas. An embodiment of the present disclosure can prevent occurrence of the phenomenon of condensation on the display screen indoors, improve the display quality.

Those skilled in the art may clearly understand that, for convenience and briefness of description, specific working processes of the above mentioned systems, devices and units may refer to corresponding processes in the aforementioned method embodiments, repeated description is no longer made herein.

The above are only preferred embodiments of the present disclosure, and are not used to limit the present disclosure. Any modifications, equivalent substitutions, improvements, etc, made within the spirit and principle of the present disclosure are to be contained within the protection scope of the present disclosure.

The above are only specific embodiments of the present disclosure, but the protection scope of the present disclosure is not limited thereto. Any changes or substitutions which may be easily conceived of by those skilled in the art within the technical scope disclosed by the present disclosure are to be covered within the protection scope of the present disclosure. Therefore, the protection scope of the present disclosure is based on the protection scope of claims.

1. A display device comprising: a transparent structure and a display screen;
the transparent structure including a first light transmission plate and a second light transmission plate which are oppositely set, edge regions of the first light transmission plate and the second light transmission plate being packaged by a seal assembly, to form a closed cavity;
the display screen being set within the closed cavity, and an edge of the display screen being fixed to an inner wall of the closed cavity; the closed cavity being filled with inert gas.

2. The display device according to claim 1, wherein in a place which is within the closed cavity and is close to the seal assembly, there is also provided with a support which supports the first light transmission plate and the second light transmission plate, the support has water absorptivity.

3. The display device according to claim 2, wherein the support includes a casing and a water absorption material poured within the casing.

4. The display device according to claim 3, wherein the casing has at least one air hole.

5. The display device according to claim 4, wherein the water absorption material is a molecular sieve or a drying adsorbent.

6. The display device according to claim 1, wherein the seal assembly includes a first structure casing, a second structure casing, a seal glue, a first shock damping adhesive tape, a second shock damping adhesive tape and a position-limit structure;
wherein, the seal glue is packaged between opposite edge regions of the first light transmission plate and the second light transmission plate, the first structure casing is set outside the first light transmission plate and the seal glue, the second structure casing is set outside the second light transmission plate and the seal glue, the first structure casing and the second structure casing are fixed by a fastening structure on one side of the seal glue which is remote a support;
the first shock damping adhesive tape is set between the first structure casing and the first light transmission plate, the second shock damping adhesive tape is set between the second structure casing and the second light transmission plate, the position-limit structure is set between the first structure casing and a joint of the first light transmission plate and the seal glue, the first shock damping adhesive tape is connected with the position-limit structure as one piece.

7. The display device according to claim 6, wherein the edge of the display screen and the first light transmission plate are fixed by an adhesive tape.

8. The display device according to claim 1, wherein ventilation openings are set in diagonal positions of the transparent structure; the ventilation openings communicate with the closed cavity; after the closed cavity is full of the inert gas, the ventilation openings are in a seal-up state.

9. The display device according to claim 7, wherein a touch screen is set on one side of the first light transmission plate which is remote from the display screen, the touch screen is connected with a touch sensor, the touch sensor is set between the first shock damping adhesive tape and the first structure casing, a third shock damping adhesive tape is further set between the touch sensor and the first structure casing.

10. The display device according to claim 1, wherein a light-emitting assembly is set outside the transparent structure, the light-emitting assembly is connected to the seal assembly.

11. The display device according to claim 10, wherein the light-emitting assembly includes a heat dissipation bracket and a light source, one end of the heat dissipation bracket is connected with the seal assembly, an other end is connected with the light source; a light out surface of the light source inclines and faces one side which is remote from the seal assembly.

12. The display device according to claim 11, wherein the heat dissipation bracket includes multiple heat dissipation columns; the heat dissipation columns are set on one side of the heat dissipation bracket which is remote from the light source.

13. The display device according to claim 12, wherein an outer surface of a heat dissipation column of the heat dissipation columns is a curved surface.

14. A display apparatus comprising the display device according to claim 1 and an apparatus body, the display device being set on at least one side of the apparatus body.

15. The display apparatus according to claim 14, wherein in a place which is within the closed cavity and is close to the seal assembly, there is also provided with a support which supports the first light transmission plate and the second light transmission plate, the support has water absorptivity.

16. The display device according to claim 15, wherein the support includes a casing and a water absorption material poured within the casing, the casing has at least one air hole, and the water absorption material is a molecular sieve or a drying adsorbent.

17. The display device according to claim 14, wherein the seal assembly includes a first structure casing, a second structure casing, a seal glue, a first shock damping adhesive tape, a second shock damping adhesive tape and a position-limit structure;
the seal glue is packaged between opposite edge regions of the first light transmission plate and the second light transmission plate, the first structure casing is set outside the first light transmission plate and the seal glue, the second structure casing is set outside the second light transmission plate and the seal glue, the first structure casing and the second structure casing are fixed by a fastening structure on one side of the seal glue which is remote from a support;
the first shock damping adhesive tape is set between the first structure casing and the first light transmission plate, the second shock damping adhesive tape is set between the second structure casing and the second light transmission plate, the position-limit structure is set between the first structure casing and a joint of the first light transmission plate and the seal glue, the first shock damping adhesive tape is connected with the position-limit structure as one piece.

18. The display device according to claim 17, wherein the edge of the display screen and the first light transmission plate are fixed by an adhesive tape; ventilation openings are set in diagonal positions of the transparent structure; the ventilation openings communicate with the closed cavity; after the closed cavity is full of the inert gas, the ventilation openings are in a seal-up state; a touch screen is set on one side of the first light transmission plate which is remote from the display screen, the touch screen is connected with a touch sensor, the touch sensor is set between the first shock damping adhesive tape and the first structure casing, a third shock damping adhesive tape is further set between the touch sensor and the first structure casing.

19. The display device according to claim 18, wherein a light-emitting assembly is set outside the transparent structure, the light-emitting assembly is connected to the seal assembly; the light-emitting assembly includes a heat dissipation bracket and a light source, one end of the heat dissipation bracket is connected with the seal assembly, an other end is connected with the light source; a light out surface of the light source inclines and faces one side which is remote from the seal assembly.

20. The display device according to claim 19, wherein the heat dissipation bracket includes multiple heat dissipation columns; the heat dissipation columns are set on one side of the heat dissipation bracket which is remote from the light source, and an outer surface of a heat dissipation column of the heat dissipation columns is a curved surface.
